(19) United States
(12) Patent Application Publication
(10) Pub. No.: US 2024/0121944 A1
(43) Pub. Date: Apr. 11, 2024

(54) SEMICONDUCTOR MEMORY DEVICE

(71) Applicant: SAMSUNG ELECTRONICS CO., LTD., Suwon-si (KR)

(72) Inventor: Young Woo KIM, Suwon-si (KR)

(21) Appl. No.: 18/227,469

(22) Filed: Jul. 28, 2023

(30) Foreign Application Priority Data
Oct. 11, 2022 (KR) 10-2022-0129850
Apr. 14, 2023 (KR) 10-2023-0049226

(51) Int. Cl. H10B 12/00

(52) U.S. Cl. CPC H10B 12/34; H10B 12/053; H10B 12/315

(57) ABSTRACT

A semiconductor memory device, including a substrate including an active region, a cell gate structure in the substrate and extended in a first direction, the cell gate structure including a cell gate trench, a cell gate insulating layer along an inner wall of the cell gate trench, a cell gate electrode on the cell gate insulating layer, a cell gate conductive layer on the cell gate electrode and a cell gate capping pattern filling the cell gate trench, a bit line structure crossing the cell gate structure, and an information storage connected to the active region, wherein the cell gate insulating layer includes an insertion portion between the cell gate conductive layer and the cell gate capping pattern, a lower portion in contact with the cell gate conductive layer, and an upper portion in contact with the cell gate capping pattern.

### CROSS-REFERENCE TO RELATED APPLICATION

Korean Patent Application No. 10-2022-0129850, filed on Oct. 11, 2022, and Korean Patent Application No. 10-2023-0049226, filed on Apr. 14, 2023, in the Korean Intellectual Property Office, are herein incorporated by reference in their entireties.

### BACKGROUND

### 1. Field

A semiconductor memory device is disclosed.

### 2. Description of the Related Art

As semiconductor devices become increasingly highly integrated, individual circuit patterns are becoming finer to implement more semiconductor devices in the same area.

### SUMMARY

Embodiments are directed to a semiconductor memory device, including a substrate including an active region, a cell gate structure in the substrate and extended in a first direction, the cell gate structure including a cell gate trench, a cell gate insulating layer along an inner wall of the cell gate trench, a cell gate electrode on the cell gate insulating layer, a cell gate conductive layer on the cell gate electrode and a cell gate capping pattern filling the cell gate trench, a bit line structure crossing the cell gate structure, and an information storage connected to the active region, wherein the cell gate insulating layer includes an insertion portion between the cell gate conductive layer and the cell gate capping pattern, a lower portion in contact with the cell gate conductive layer, and an upper portion in contact with the cell gate capping pattern, and a first thickness of a first portion of the upper portion of the cell gate insulating layer is greater than a second thickness of the lower portion of the cell gate insulating layer.

Embodiments are directed to a semiconductor memory device, including a substrate including an active region, a first cell gate trench in the substrate, having a first width, a first cell gate insulating layer along a first inner wall of the first cell gate trench, a first cell gate electrode on the first cell gate insulating layer, a first cell gate conductive layer on the first cell gate electrode, a first insulating liner layer on the first cell gate conductive layer, a first cell gate capping pattern on the first insulating liner layer, a second cell gate trench in the substrate, having a second width greater than the first width, a second cell gate insulating layer along a second inner wall of the second cell gate trench, a second cell gate electrode on the second cell gate insulating layer, a second cell gate conductive layer on the second cell gate electrode, a second insulating liner layer on the second cell gate conductive layer, and a second cell gate capping pattern on the second insulating liner layer, wherein a first distance from an upper surface of the first cell gate capping pattern to an upper surface of the first cell gate conductive layer is equal to a second distance from an upper surface of the second cell gate capping pattern to an upper surface of the second cell gate conductive layer.

Embodiments are directed to a semiconductor memory device, including a substrate including an active region, a cell gate structure in the substrate and extended in a first direction, including a cell gate trench, a cell gate insulating layer along an inner wall of the cell gate trench, a cell gate electrode on the cell gate insulating layer, a cell gate conductive layer on the cell gate electrode and a cell gate capping pattern filling the cell gate trench, a bit line structure crossing the cell gate structure, and an information storage connected to the active region, wherein the cell gate trench includes a first trench and a second trench below the first trench, and a first sidewall of the first trench and a second sidewall of the second trench are not on the same line.

### BRIEF DESCRIPTION OF DRAWINGS

Features will become apparent to those of skill in the art by describing in detail exemplary embodiments with reference to the attached drawings in which:

FIG. 1 is a layout showing a semiconductor memory device according to example embodiments.

FIG. 2 is a layout showing only a word line and an active region of FIG. 1.

FIG. 3 is an example cross-sectional view taken along line A-A of FIG. 1.

FIG. 4 is an example cross-sectional view taken along line B-B of FIG. 1.

FIG. 5 is an enlarged view showing an area Q1 of FIG. 4.

FIG. 6 is an example cross-sectional view taken along line C-C of FIG. 1

FIG. 7 is a view showing a semiconductor memory device according to example embodiments.

FIG. 8 is an enlarged view showing a region Q2 of FIG. 7.

FIGS. 9 and 10 are views showing a semiconductor memory device according to example embodiments.

FIG. 11 is an enlarged view showing a region Q3 of FIG. 10.

FIG. 12 is a view showing a semiconductor memory device according to example embodiments.

FIG. 13 is an enlarged view showing a region P of FIG. 12.

FIGS. 14 to 24 are views showing intermediate steps to describe a method for fabricating a semiconductor memory device according to example embodiments.

FIGS. 25 and 26 are views showing intermediate steps to describe a method for fabricating a semiconductor memory device according to example embodiments.

FIGS. 27 to 32 are views showing intermediate steps to describe a method for fabricating a semiconductor memory device according to example embodiments.

### DETAILED DESCRIPTION

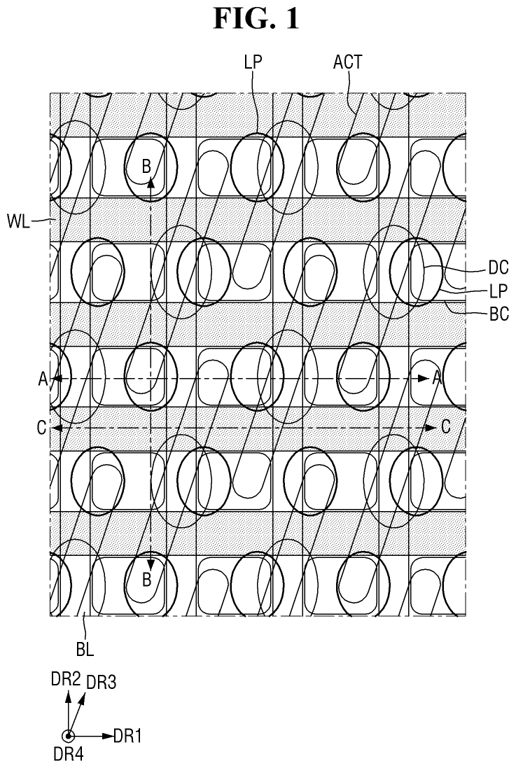

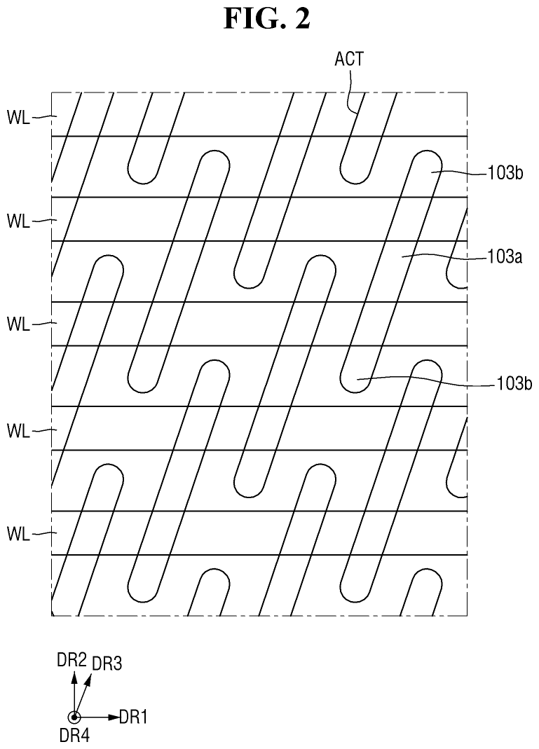

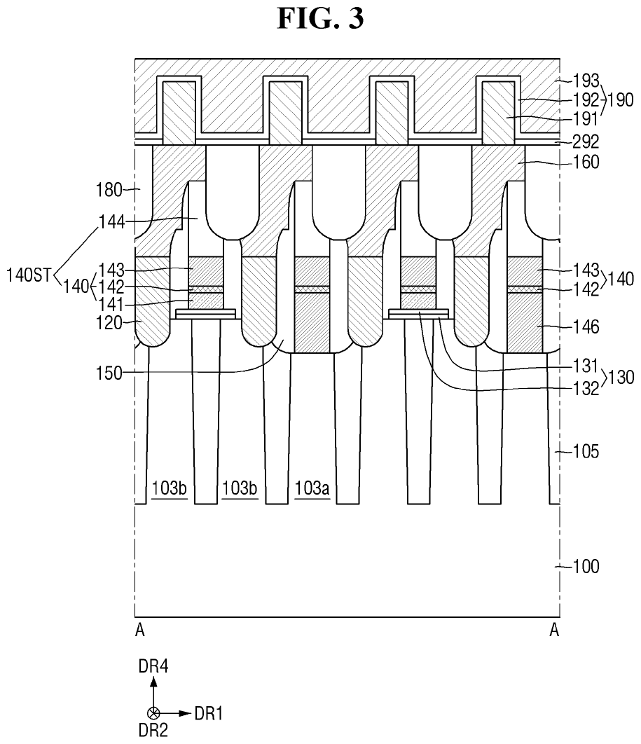

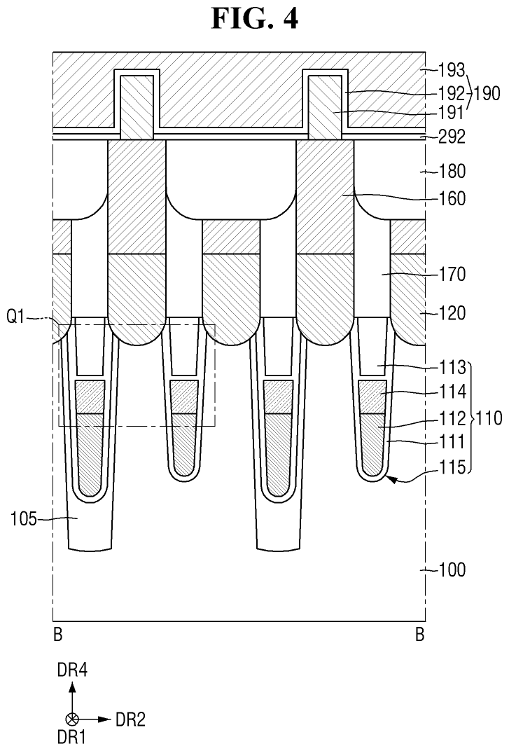

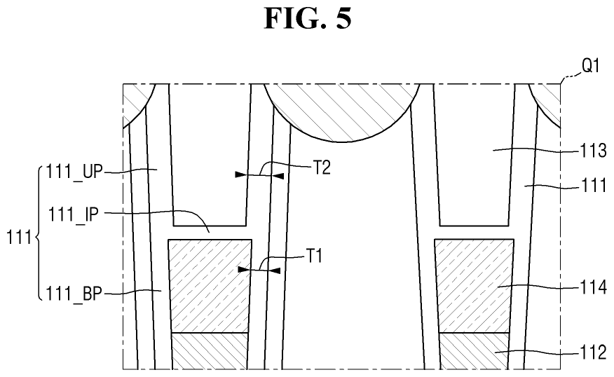

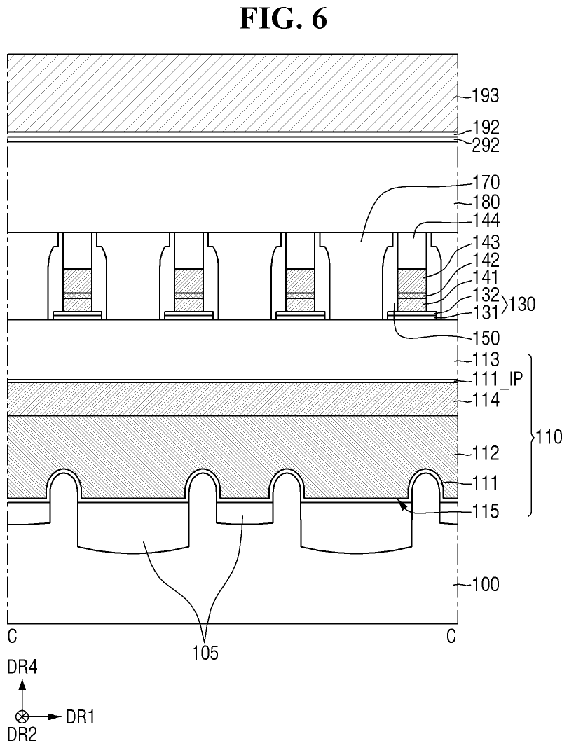

FIG. 1 is a layout showing a semiconductor memory device according to example embodiments. FIG. 2 is a layout showing only a word line and an active region of FIG. 1. FIG. 3 is an example cross-sectional view taken along line A-A of FIG. 1. FIG. 4 is an example cross-sectional view taken along line B-B of FIG. 1. FIG. 5 is an enlarged view showing an area Q1 of FIG. 4. FIG. 6 is an example cross-sectional view taken along line C-C of FIG. 1.

A dynamic random access memory (DRAM) is shown in the drawing as a semiconductor memory device according to example embodiments. Referring to FIGS. 1 and 2, the semiconductor memory device according to some embodiments may include a plurality of cell active regions ACT.

The plurality of cell active regions ACT may be defined by a cell element isolation layer 105 formed in a substrate (100 of FIG. 3). As a design rule of the semiconductor memory device is reduced, the plurality of cell active regions ACT may be disposed in a bar shape of a diagonal line or an oblique line as shown. In an implementation, each of the plurality of cell active regions ACT may be extended in a third direction DR3. As used herein, the term “or” is not an exclusive term, e.g., “A or B” would include A, B, or A and B.

A plurality of gate electrodes may be disposed in a first direction DR1 across the cell active region ACT. The plurality of gate electrodes may be extended in parallel with each other. The plurality of gate electrodes may be, e.g., a plurality of word lines WL. The word lines WL may be disposed at constant intervals. A width of the word line WL or an interval between the word lines WL may be determined in accordance with the design rule.

Each of the plurality of cell active regions ACT may be divided into three portions by two word lines WL extended in the first direction DR1. The plurality of cell active regions ACT may include a storage connection portion 103b and a bit line connection portion 103a. The bit line connection portion 103a may be positioned at a center portion of each of the plurality of cell active regions ACT, and the storage connection portion 103b may be positioned at an end portion of each of the plurality of cell active regions ACT.

In an implementation, the bit line connection portion 103a may be an area connected to a bit line BL and the storage connection portion 103b may be an area connected to an information storage (190 of FIG. 3). In other words, the bit line connection portion 103a may correspond to a common drain area, and the storage connection portion 103b may correspond to a source area. Each word line WL, the bit line connection portion 103a adjacent thereto and the storage connection portion 103b may constitute a transistor.

A plurality of bit lines BL, which may be orthogonal to the word line WL and extended in a second direction DR2, may be on the word line WL. The plurality of bit lines BL may be extended in parallel with each other. The bit lines BL may be disposed at constant intervals. A width of the bit line BL or an interval between the word lines BL may be determined in accordance with the design rule.

A fourth direction DR4 may be orthogonal to the first direction DR1, the second direction DR2 and the third direction DR3. The fourth direction DR4 may be a thickness direction of the substrate 100.

The semiconductor memory device according to some embodiments may include various contact arrangements formed on the cell active region ACT. The various contact arrangements may include, e.g., a direct contact DC, a buried contact BC, or a landing pad LP.

The direct contact DC may refer to a contact that electrically connects the cell active region to the bit line BL. The buried contact BC may refer to a contact that may connect each of the plurality of cell active regions ACT to a lower electrode (191 of FIG. 3) of a capacitor. A contact area between the buried contact BC and a cell active region of the plurality of cell active regions ACT may be small in view of an arrangement structure. Therefore, a conductive landing pad LP may be introduced to enlarge the contact area with the lower electrode (191 of FIG. 3) of the capacitor together with the contact area with the cell active region ACT.

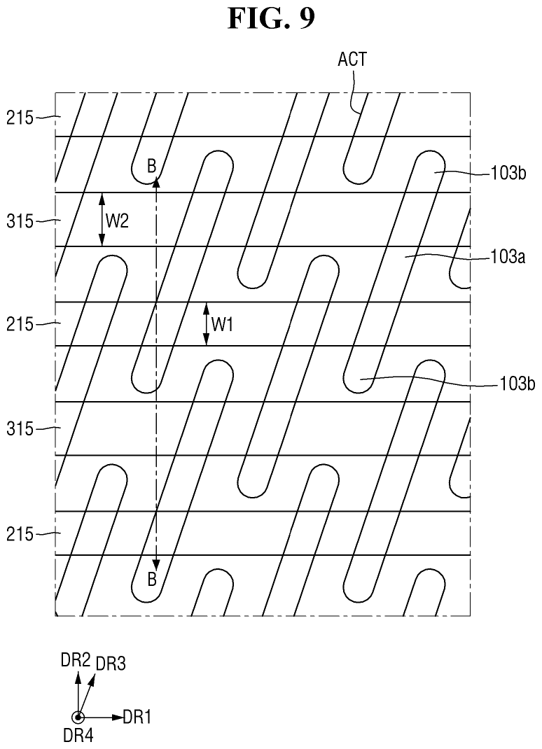

The landing pad LP may be between each of the plurality of cell active regions ACT and the buried contact BC, and may be between the buried contact BC and the lower electrode (191 of FIGS. 6 and 9) of the capacitor. In the semiconductor memory device according to some embodiments, the landing pad LP may be between the buried contact BC and the lower electrode (191 of FIG. 3) of the capacitor. As the contact area is enlarged through the introduction of the landing pad LP, contact resistance between the plurality of cell active regions ACT and the lower electrode of the capacitor may be reduced.

The direct contact DC may be connected to the bit line connection portion 103a. The buried contact BC may be connected to the storage connection portion 103b. As the buried contact BC is at both end portions of the cell active region ACT, the landing pad LP may partially overlap the buried contact BC in a state that it is adjacent to both ends of the cell active region ACT. In other words, the buried contact BC may overlap the plurality of cell active regions ACT and the cell element isolation layer (105 of FIGS. 3 and 4) between adjacent word lines WL and between adjacent bit lines BL.

The word line WL may be in a structure buried in the substrate 100. The word line WL may be across the plurality of cell active regions ACT and between the direct contacts DC or the buried contacts BC. Two word lines WL may cross one cell active region ACT of the plurality of cell active regions ACT. As each of the plurality of cell active regions ACT may be extended along the third direction DR3, the word line WL may have an angle less than 90° with each of the plurality of cell active regions ACT.

The direct contact DC and the buried contact BC may be symmetrically disposed. For this reason, the direct contact DC and the buried contact BC may be on a straight line along the first direction DR1 and the second direction DR2. Unlike the direct contact DC and the buried contact BC, the landing pad LP may be disposed in a zigzag shape in the second direction DR2 in which the bit line BL is extended. In addition, the landing pad LP may overlap the same side portion of each bit line BL in the first direction DR1 in which the word line WL is extended.

In an implementation, each landing pad LP of a first line may overlap a left side of a corresponding bit line BL, and each landing pad LP of a second line may overlap a right side of a corresponding bit line BL.

Referring to FIGS. 1 to 6, the semiconductor memory device according to some embodiments may include a plurality of cell gate structures 110, a plurality of bit line structures 140ST, a plurality of bit line contacts 146 and an information storage 190.

The substrate 100 may be a silicon substrate or a silicon-on-insulator (SOI). Alternatively, the substrate 100 may include silicon germanium, silicon germanium on insulator (SGOI), indium antimonide, lead telluride compound, indium arsenide, indium phosphide, gallium arsenide or gallium antimonide.

The cell element isolation layer 105 may be in the substrate 100. The cell element isolation layer 105 may have a shallow trench isolation (STI) structure having excellent element isolation characteristics. The cell element isolation layer 105 may define the plurality of cell active regions ACT in a memory cell area.

The plurality of cell active regions ACT defined by the cell element isolation layer 105 may have a long island shape including a short axis and a long axis as shown in FIGS. 1 and 2. Each of the plurality of cell active regions ACT may have an oblique shape and may have an angle less than 90° with respect to the word line WL in the cell element isolation layer 105. In addition, each of the plurality of cell active regions ACT may have an oblique shape to have an angle less than 90° with respect to the bit line BL on the cell element isolation layer 105.

The cell element isolation layer 105 may include, a silicon oxide layer, a silicon nitride layer or a silicon oxynitride layer. The cell element isolation layer 105 may be formed of one insulating layer. The cell element isolation layer 105 may be formed of one insulating layer or a plurality of insulating layers depending on a distance at which each of the plurality of adjacent cell active regions ACT are spaced apart from each other.

In FIG. 3, an upper surface of the cell element isolation layer 105 and an upper surface of the substrate 100 may be placed on the same plane. A height level of the upper surface of the cell element isolation layer 105 shown in FIG. 3 may be different from that of the upper surface of the cell element isolation layer 105 shown in FIG. 4 due to a variation of a fabricating process.

The cell gate structure 110 may be in the substrate 100 and the cell element isolation layer 105. The cell gate structure 110 may be formed across the cell element isolation layer 105 and the plurality of cell active regions ACT defined by the cell element isolation layer 105.

The cell gate structure 110 may be in the substrate 100 and the cell element isolation layer 105. The cell gate structure 110 may include a cell gate trench 115, a cell gate insulating layer 111, a cell gate electrode 112, a cell gate capping pattern 113 and a cell gate conductive layer 114.

In this case, the cell gate electrode 112 may correspond to the word line WL. In an implementation, the cell gate electrode 112 may be the word line WL of FIG. 1. The cell gate structure 110 may not include the cell gate conductive layer 114.

As shown in FIG. 6, the cell gate trench 115 may be relatively deep in the cell element isolation layer 105, and may be relatively shallow in the cell active regions ACT. A bottom surface of the word line WL may be curved. In an implementation, a depth of the cell gate trench 115 in the cell element isolation layer 105 may be greater than that of the cell gate trench 115 in the cell active region ACT.

Referring to FIGS. 4 and 5, the cell gate insulating layer 111 may be extended along sidewalls and a bottom surface of the cell gate trench 115. The cell gate insulating layer 111 may be extended along a profile of at least a portion of the cell gate trench 115.

The cell gate insulating layer 111 may include an upper portion 111_UP, a lower portion 111_BP and an insertion portion 111_IP.

The lower portion 111_BP of the cell gate insulating layer 111 may be in contact with the cell gate conductive layer 114 and the cell gate electrode 112. The lower portion 111_BP of the cell gate insulating layer 111 may have a first thickness T1. In this case, the first thickness T1 may be a thickness in the second direction DR2 in view of a cross-sectional area.

The upper portion 111_UP of the cell gate insulating layer 111 may be in contact with the cell gate capping pattern 113. The upper portion 111_UP of the cell gate insulating layer 111 may have a second thickness T2. The second thickness T2 may be a thickness in the second direction DR2 in view of the cross-sectional area. The second thickness T2 may be defined as a thickness at a portion that is not between the upper portion 111_UP of the cell gate insulating layer 111 and the storage contact 120.

In some embodiments, the first thickness T1 may be different from the second thickness T2. In an implementation, the second thickness T2 may be greater than the first thickness T1. The first thickness T1 may be the same as or smaller than the second thickness T2.

The insertion portion 111_IP of the cell gate insulating layer 111 may be on an upper surface of the cell gate conductive layer 114. The insertion portion 111_IP of the cell gate insulating layer 111 may be on a lower surface of the cell gate capping pattern 113. In an implementation, the cell gate capping pattern 113 and the cell gate conductive layer 114 may be spaced apart from each other by the insertion portion 111_IP of the cell gate insulating layer 111. The insertion portion 111_IP and the lower portion 111_BP of the cell gate insulating layer 111 may surround the cell gate conductive layer 114.

A thickness of the insertion portion 111_IP of the cell gate insulating layer 111 may be smaller than the second thickness T2. In an implementation, the thickness of the insertion portion 111_IP of the cell gate insulating layer 111 may be the same as the second thickness T2. The thickness of the insertion portion 111_IP of the cell gate insulating layer 111 may be a thickness in the fourth direction DR4. In other words, the thickness of the insertion portion 111_IP of the cell gate insulating layer 111 may be a distance from the upper surface of the cell gate conductive layer 114 to the lower surface of the cell gate capping pattern 113.

The cell gate insulating layer 111 may include, e.g., silicon oxide, silicon nitride, silicon oxynitride, or a high dielectric constant material having a dielectric constant higher than that of silicon oxide. The high dielectric constant material may include boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The cell gate electrode 112 may be on the cell gate insulating layer 111. The cell gate electrode 112 may fill a portion of the cell gate trench 115. The cell gate electrode 112 may be surrounded by the cell gate insulating layer 111.

The cell gate electrode 112 may include a metal, a metal alloy, a conductive metal nitride, a conductive metal carbonitride, a conductive metal carbide, a metal silicide, a doped semiconductor material, a conductive metal oxynitride or a conductive metal oxide. The cell gate electrode 112 may include, e.g., TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, or RuOx.

The cell gate conductive layer 114 may be on the cell gate electrode 112. The cell gate conductive layer 114 may be extended along the upper surface of the cell gate electrode 112. The cell gate conductive layer 114 may cover the upper surface of the cell gate electrode 112. The cell gate conductive layer 114 may overlap the cell gate electrode 112 in the fourth direction DR4. Both sidewalls of the cell gate conductive layer 114 may be in contact with the cell gate insulating layer 111. The cell gate conductive layer 114 may be surrounded by the cell gate insulating layer 111.

The cell gate conductive layer 114 may include a semiconductor material. The cell gate conductive layer 114 may include one of, e.g., polysilicon, polysilicon-germanium, amorphous silicon, or amorphous silicon-germanium.

In some embodiments, the cell gate conductive layer 114 may include N-type impurities. In an implementation, a concentration of the N-type impurities of the cell gate conductive layer 114 may be constant. For another example, the concentration of the N-type impurities of the cell gate conductive layer 114 may be greater in an upper portion than in a lower portion. The N-type impurities may include, e.g., phosphorus (P), arsenic (As), antimony (Sb), or bismuth (Bi).

The cell gate capping pattern 113 may be on the cell gate electrode 112 and the cell gate conductive layer 114. The cell gate capping pattern 113 may fill the cell gate trench 115 remaining after the cell gate electrode 112 and the cell gate conductive layer 114 are formed. The cell gate insulating layer 111 may be extended along sidewalls of the cell gate capping pattern 113.

The cell gate capping pattern 113 may include, e.g., silicon nitride (SiN), silicon oxynitride (SiON), silicon oxide (SiO₂), silicon carbonitride (SiCN), or silicon oxycarbonitride (SiOCN).

In FIG. 4, the upper surface of the cell gate capping pattern 113 may be coplanar with the upper surface of the cell element isolation layer 105. As shown in FIG. 3, an impurity doping region may be on at least one side of the cell gate structure 110. The impurity doping region may be a source/drain region of a transistor. The impurity doping region may correspond to the storage connection portion 103b and the bit line connection portion 103a of FIG. 2.

In FIG. 2, when a transistor, which includes each word line WL, and the bit line connection portion 103a and the storage connection portion 103b, (which may be adjacent to each word line WL), is an NMOS transistor, the storage connection portion 103b and the bit line connection portion 103a may include doped n-type impurities, e.g., phosphorus (P), arsenic (As), antimony (Sb), or bismuth (Bi). When the transistor, which may include each word line WL, and the bit line connection portion 103a and the storage connection portion 103b, (which may be adjacent to each word line WL), is a PMOS transistor, the storage connection portion 103b and the bit line connection portion 103a may include doped P-type impurities, e.g., boron (B).

The bit line structure 140ST may include a cell conductive line 140, a cell line capping layer 144, and a bit line spacer 150.

The cell conductive line 140 may be on the substrate 100, on which the cell gate structure 110 may be formed, and the cell element isolation layer 105. The cell conductive line 140 may cross the cell element isolation layer 105 and the plurality of cell active regions ACT defined by the cell element isolation layer 105. The cell conductive line 140 may cross the cell gate structure 110. In this case, the cell conductive line 140 may correspond to the bit line BL. In an implementation, the cell conductive line 140 may be the bit line BL of FIG. 1.

The cell conductive line 140 may include, e.g., a semiconductor material doped with impurities, a conductive silicide compound, a conductive metal nitride, a two-dimensional (2D) material, a metal, or a metal alloy. In the semiconductor memory device according to some embodiments, the two-dimensional material may be a metallic material or a semiconductor material. The two-dimensional (2D) material may include a two-dimensional allotrope or a two-dimensional compound, and may include, e.g., graphene, molybdenum disulfide (MoS₂), molybdenum diselenide (MoSe₂), tungsten diselenide (WSe₂) or tungsten disulfide (WS₂).

The cell conductive line 140 may be a single layer. In an implementation, the cell conductive line 140 may include a plurality of conductive layers in which conductive materials may be stacked.

The cell line capping layer 144 may be on the cell conductive line 140. The cell line capping layer 144 may be extended in the second direction DR2 along an upper surface of the cell conductive line 140. The cell line capping layer 144 may include, e.g., silicon nitride, silicon oxynitride, silicon carbonitride, or silicon oxycarbonitride.

In the semiconductor memory device according to some embodiments, the cell line capping layer 144 may include a silicon nitride layer. The cell line capping layer 144 may be a single layer.

The bit line spacer 150 may be on sidewalls of the cell conductive line 140 and the cell line capping layer 144. The bit line spacer 150 may be extended to be elongated in the second direction DR2.

The bit line spacer 150 may be a single layer. In an implementation, the bit line spacer 150 may have a multi-layered structure. The bit line spacer 150 may include one of, e.g., a silicon oxide layer, a silicon nitride layer, a silicon oxynitride (SiON) layer, a silicon oxycarbonitride (SiOCN) layer, or air.

The cell insulating layer 130 may be on the substrate 100 and the cell element isolation layer 105. In more detail, the cell insulating layer 130 may be on the upper surface of the cell element isolation layer 105 and the substrate 100 on which the bit line contact 146 and a storage contact 120 may not be formed. The cell insulating layer 130 may be between the substrate 100 and the cell conductive line 140 and between the cell element isolation layer 105 and the cell conductive line 140.

The cell insulating layer 130 may be a single layer, but may be a multi-layer that may include a first cell insulating layer 131 and a second cell insulating layer 132, as shown. In an implementation, the first cell insulating layer 131 may include a silicon oxide layer, and the second cell insulating layer 132 may include a silicon nitride layer. The cell insulating layer 130 may be a triple layer that may include a silicon oxide layer, a silicon nitride layer, and a silicon oxide layer. As used herein, the terms “first,” “second,” and the like are merely for identification and differentiation, and are not intended to imply or require sequential inclusion (e.g., a third element and a fourth element may be described without implying or requiring the presence of a first element or second element).

The bit line contact 146 may be between the cell conductive line 140 and the substrate 100. The cell conductive line 140 may be on the bit line contact 146. The bit line contact 146 may be between the bit line connection portion 103a of the plurality of cell active regions ACT and the cell conductive line 140. The bit line contact 146 may electrically connect the cell conductive line 140 with the substrate 100. The bit line contact 146 may be connected with the bit line connection portion 103a.

The bit line contact 146 may include an upper surface connected to the cell conductive line 140. A width of the bit line contact 146 in the first direction DR1 may be constant as it becomes far away from the upper surface of the bit line contact 146.

The bit line contact 146 may correspond to the direct contact DC. The bit line contact 146 may include, e.g., a semiconductor material doped with impurities, a conductive metal silicide, a conductive metal nitride, a conductive metal oxide, a metal, or a metal alloy.

In a portion of the cell conductive line 140, in which the bit line contact 146 may be formed, the bit line spacer 150 may be on the substrate 100 and the cell element isolation layer 105. The bit line spacer 150 may be on sidewalls of the cell conductive line 140, the cell line capping layer 144, and the bit line contact 146.

In the other portion of the cell conductive line 140, in which the bit line contact 146 may not be formed, the bit line spacer 150 may be on the cell insulating layer 130. The bit line spacer 150 may be on the sidewalls of the cell conductive line 140 and the cell line capping layer 144.

A fence pattern 170 may be on the substrate 100 and the cell element isolation layer 105. The fence pattern 170 may overlap the substrate 100 and the cell gate structure 110 formed in the cell element isolation layer 105.

The fence pattern 170 may be between bit line structures 140ST extended in the second direction DR2. The fence pattern 170 may include, e.g., silicon oxide, silicon nitride, or silicon oxynitride.

The storage contact 120 may be between the cell conductive lines 140 adjacent to each other in the first direction DR1. The storage contact 120 may be at both sides of the cell conductive line 140. In more detail, the storage contact 120 may be between the bit line structures 140ST. The storage contact 120 may be between the fence patterns 170 adjacent to each other in the second direction DR2.

The storage contact 120 may overlap the substrate 100 and the cell element isolation layer 105 between the adjacent cell conductive lines 140. The storage contact 120 may be connected to the cell active region ACT. In more detail, the storage contact 120 may be connected to the storage connection portion 103b. In this case, the storage contact 120 may correspond to the buried contact BC of FIG. 1.

The storage contact 120 may include, e.g., a semiconductor material doped with impurities, a conductive silicide compound, a conductive metal nitride, or a metal. A storage pad 160 may be on the storage contact 120. The storage pad 160 may be electrically connected to the storage contact 120. The storage pad 160 may be connected to the storage connection portion 103b of the cell active region ACT. In this case, the storage pad 160 may correspond to the landing pad LP.

The storage pad 160 may overlap a portion of an upper surface of the bit line structure 140ST. The storage pad 160 may include, e.g., a conductive metal nitride, a conductive metal carbide, a metal, or a metal alloy.

A pad isolation insulating layer 180 may be on the storage pad 160 and the bit line structure 140ST. In an implementation, the pad isolation insulating layer 180 may be on the cell line capping layer 144. The pad isolation insulating layer 180 may define the storage pad 160 that may form a plurality of isolation regions. The pad isolation insulating layer 180 may not cover an upper surface of the storage pad 160. In an implementation, based on the upper surface of the substrate 100, a height of the upper surface of the storage pad 160 may be the same as that of an upper surface of the pad isolation insulating layer 180.

The pad isolation insulating layer 180 may include an insulating material, and may electrically isolate the plurality of storage pads 160 from each other. In an implementation, the pad isolation insulating layer 180 may include, e.g., a silicon oxide layer, a silicon nitride layer, a silicon oxynitride layer, a silicon oxycarbonitride layer, or a silicon carbonitride layer.

An etch stop layer 165 may be on the upper surface of the storage pad 160 and the upper surface of the pad isolation insulating layer 180. The etch stop layer 165 may include, e.g., silicon nitride (SiN), silicon carbonitride (SiCN), silicon oxycarbonitride (SiOCN), silicon oxycarbide (SiOC), or silicon boron nitride (SiBN).

The information storage 190 may be on the storage pad 160. The information storage 190 may be connected to the storage pad 160. A portion of the information storage 190 may be disposed in the etch stop layer 165.

The information storage 190 may include, e.g., a capacitor. The information storage 190 may include a lower electrode 191, a capacitor dielectric layer 192, and an upper electrode 193. In an implementation, the upper electrode 193 may be a plate upper electrode having a plate shape.

The lower electrode 191 may be on the storage pad 160. The lower electrode 191 may have, e.g., a pillar shape. The capacitor dielectric layer 192 may be on the lower electrode 191. The capacitor dielectric layer 192 may be formed along a profile of the lower electrode 191. The upper electrode 193 may be on the capacitor dielectric layer 192. The upper electrode 193 may surround outer sidewalls of the lower electrode 191. The upper electrode 193 may be a single layer.

Each of the lower electrode 191 and the upper electrode 193 may include, e.g., a doped semiconductor material, a conductive metal nitride (e.g., titanium nitride, tantalum nitride, niobium nitride or tungsten nitride), a metal (e.g., ruthenium, iridium, titanium or tantalum), or a conductive metal oxide (e.g., iridium oxide or niobium oxide).

The capacitor dielectric layer 192 may include one of, e.g., silicon oxide, silicon nitride, silicon oxynitride, or a high dielectric constant material. In the semiconductor memory device according to some embodiments, the capacitor dielectric layer 192 may include a stacked layer structure in which zirconium oxide, aluminum oxide and zirconium oxide may be sequentially stacked. In the semiconductor memory device according to some embodiments, the capacitor dielectric layer 192 may include a dielectric layer containing hafnium (Hf). In the semiconductor memory device according to some embodiments, the capacitor dielectric layer 192 may have a stacked layer structure of a ferroelectric material layer and a paraelectric material layer.

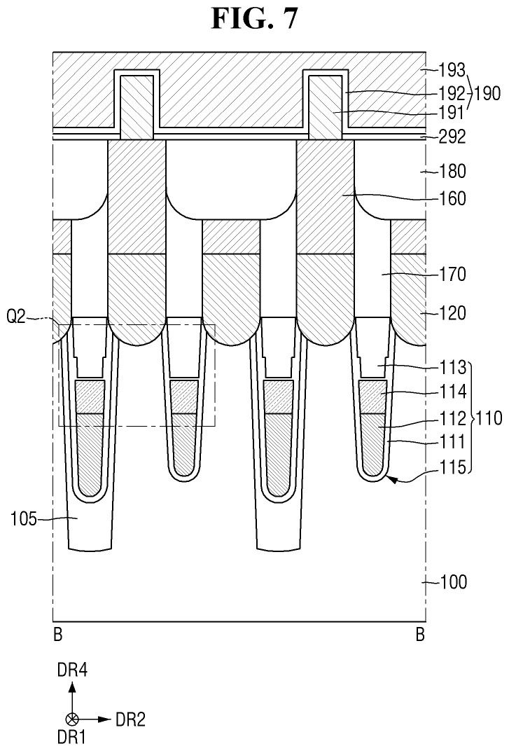

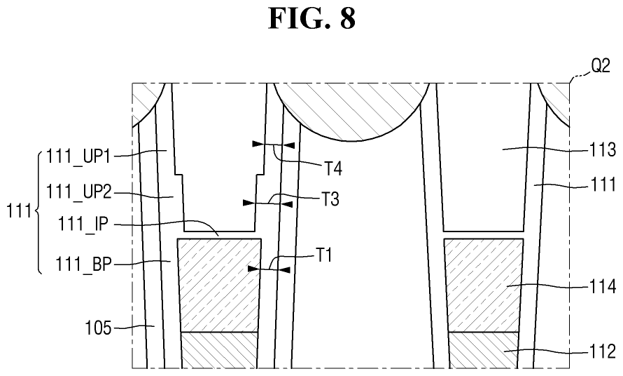

FIG. 7 is a view showing a semiconductor memory device according to example embodiments. FIG. 8 is an enlarged view showing a region Q2 of FIG. 7. For convenience of description, portions duplicated with those described with reference to FIGS. 1 to 6 will be briefly described or omitted.

Referring to FIGS. 7 and 8, the cell gate insulating layer 111 may include an upper portion 111_UP, a lower portion 111_BP and an insertion portion 111_IP.

The lower portion 111_BP of the cell gate insulating layer 111 may be in contact with the cell gate conductive layer 114 and the cell gate electrode 112. The lower portion 111_BP of the cell gate insulating layer 111 may have a first thickness T1. The first thickness T1 may be a thickness in the second direction DR2 in view of the cross-sectional area.

The upper portion of the cell gate insulating layer 111 may include a first portion 111_UP1 and a second portion 111_UP2. The upper portion 111_UP of the cell gate insulating layer 111 may be in contact with the cell gate capping pattern 113. The first portion 111_UP1 may be in contact with an upper portion of the cell gate capping pattern 113. The second portion 111_UP2 may be in contact with a lower portion of the cell gate capping pattern 113. The second portion 111_UP2 may be between the first portion 111_UP1 and the lower portion 111_BP.

The first portion 111_UP1 may have a fourth thickness T4. The second portion 111_UP2 may have a third thickness T3. The third thickness T3 may be greater than the fourth thickness T4. In an implementation, the upper portion 111_UP of the cell gate insulating layer 111 may include a stair shape in view of a cross-sectional area. In other words, a line, in which the first portion 111_UP1 and the cell gate capping pattern 113 may be in contact with each other, and a line, in which the second portion 111_UP2 and the cell gate capping pattern 113 may be in contact with each other, may not be on the same line in view of the cross-sectional area.

In the semiconductor memory device according to some embodiments, a third thickness T3 may be greater than a first thickness T1. The fourth thickness T4 may be the same as the first thickness T1. The fourth thickness T4 may be greater than the first thickness T1.

The insertion portion 111_IP of the cell gate insulating layer 111 may be on the upper surface of the cell gate conductive layer 114. The insertion portion 111_IP of the cell gate insulating layer 111 may be on the lower surface of the cell gate capping pattern 113. In an implementation, the cell gate capping pattern 113 and the cell gate conductive layer 114 may be spaced apart from each other by the insertion portion 111_IP of the cell gate insulating layer 111.

A thickness of the insertion portion 111_IP of the cell gate insulating layer 111 may be smaller than the fourth thickness T4. In an implementation, the thickness of the insertion portion 111_IP of the cell gate insulating layer 111 may be the same as the fourth thickness T4. The thickness of the insertion portion 111_IP of the cell gate insulating layer 111 may be that in the fourth direction DR4.

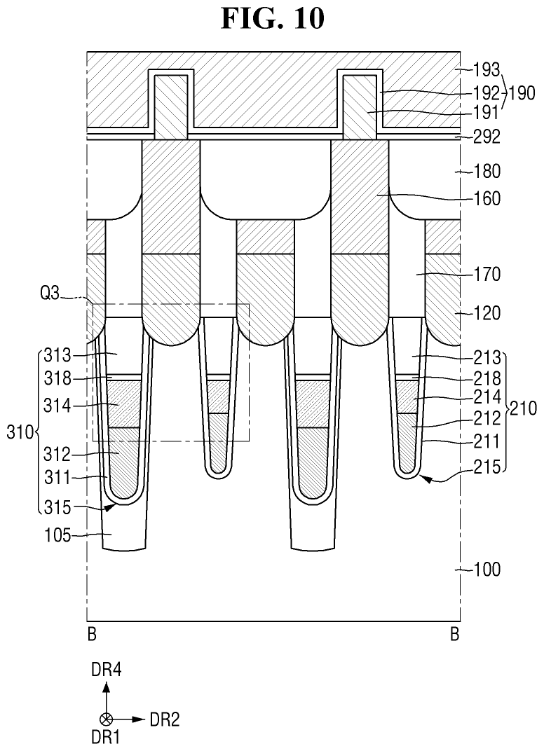

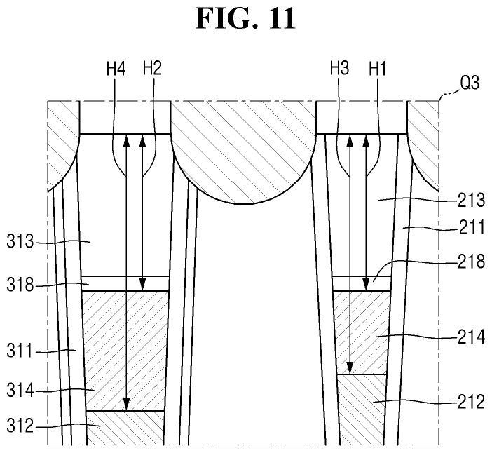

FIGS. 9 and 10 are views showing a semiconductor memory device according to example embodiments. FIG. 11 is an enlarged view showing a region Q3 of FIG. 10. For reference, FIG. 9 is a layout showing only the trench and the active region of FIG. 1. For convenience of description, redundant portions repeated with those described with reference to FIGS. 1 to 6 will be briefly described or omitted.

Referring to FIGS. 9 to 11, the semiconductor memory device according to some embodiments may include a first cell gate structure 210 and a second cell gate structure 310. The first cell gate structure 210 may be formed in the substrate 100 and the cell element isolation layer 105. The first cell gate structure 210 may include a first cell gate trench 215, a first cell gate insulating layer 211, a first cell gate electrode 212, a first insulating liner layer 218, a first cell gate capping pattern 213 and a first cell gate conductive layer 214.

The first cell gate trench 215 may be extended in the first direction DR1. The first cell gate trench 215 may have a first width W1. The first width W1 may be a width in the second direction DR2.

The first cell gate insulating layer 211 may be extended along sidewalls and a bottom surface of the first cell gate trench 215. The first cell gate insulating layer 211 may be extended along a profile of at least a portion of the first cell gate trench 215. The description of the material of the first cell gate insulating layer 211 may be the same as that of the cell gate insulating layer 111 described above.

The first cell gate electrode 212 may be on the first cell gate insulating layer 211. The first cell gate electrode 212 may fill a portion of the first cell gate trench 215.

The first cell gate conductive layer 214 may be on the first cell gate electrode 212. The first cell gate conductive layer 214 may be extended along an upper surface of the first cell gate electrode 212. Both sidewalls of the first cell gate conductive layer 214 may be in contact with the first cell gate insulating layer 211.

The first insulating liner layer 218 may be on the first cell gate conductive layer 214. The first insulating liner layer 218 may be extended along an upper surface of the first cell gate conductive layer 214. The first insulating liner layer 218 may cover the upper surface of the first cell gate conductive layer 214.

The first insulating liner layer 218 may include an insulating material. The first insulating liner layer 218 may include the same material as that of the first cell gate insulating layer 211. A boundary between the first insulating liner layer 218 and the first cell gate insulating layer 211 may not be distinguished.

The first cell gate capping pattern 213 may be on the first cell gate conductive layer 214. The first cell gate capping pattern 213 may fill the first cell gate trench 215 remaining after the first cell gate electrode 212 and the first cell gate conductive layer 214 are formed.

The second cell gate structure 310 may be in the substrate 100 and the cell element isolation layer 105. The second cell gate structure 310 may include a second cell gate trench 315, a second cell gate insulating layer 311, a second cell gate electrode 312, a second insulating liner layer 318, a second cell gate capping pattern 313 and a second cell gate conductive layer 314.

The second cell gate trench 315 may be extended in the first direction DR1. The second cell gate trench 315 may have a second width W2. The second width W2 may be width in the second direction DR2. The second width W2 may be greater than the first width W1.

The first cell gate trench 215 and the second cell gate trench 315 may be alternately disposed in the second direction DR2. The second cell gate insulating layer 311 may be extended along sidewalls and a bottom surface of the second cell gate trench 315. The second cell gate insulating layer 311 may be extended along a profile of at least a portion of the second cell gate trench 315. The description of the material of the second cell gate insulating layer 311 may be the same as that of the cell gate insulating layer 111 described above.

The second cell gate electrode 312 may be on the second cell gate insulating layer 311. The second cell gate electrode 312 may fill a portion of the second cell gate trench 315.

The second cell gate conductive layer 314 may be on the second cell gate electrode 312. The second cell gate conductive layer 314 may be extended along an upper surface of the second cell gate electrode 312. Both sidewalls of the second cell gate conductive layer 314 may be in contact with the second cell gate insulating layer 311.

The second insulating liner layer 318 may be on the second cell gate conductive layer 314. The second insulating liner layer 318 may be extended along an upper surface of the second cell gate conductive layer 314. The second insulating liner layer 318 may cover the upper surface of the second cell gate conductive layer 314.

The second insulating liner layer 318 may include an insulating material. The second insulating liner layer 318 may include the same material as that of the second cell gate insulating layer 311. A boundary between the second insulating liner layer 318 and the second cell gate insulating layer 311 may not be distinguished.

The second cell gate capping pattern 313 may be on the second cell gate conductive layer 314. The second cell gate capping pattern 313 may fill the second cell gate trench 315 remaining after the second cell gate electrode 312 and the second cell gate conductive layer 314 are formed.

Referring back to FIGS. 10 and 11, a distance H1 from the upper surface of the first cell gate capping pattern 213 to the upper surface of the first cell gate conductive layer 214 and a distance H2 from an upper surface of the second cell gate capping pattern 313 to the upper surface of the second cell gate conductive layer 314 may be the same as each other. In other words, a height from the lower surface of the substrate 100 to the upper surface of the first cell gate conductive layer 214 and a height from the lower surface of the substrate 100 to the upper surface of the second cell gate conductive layer 314 may be the same as each other.

A thickness of the first cell gate conductive layer 214 may be smaller than that of the second cell gate conductive layer 314. A distance H3 from the upper surface of the first cell gate capping pattern 213 to the lower surface of the first cell gate conductive layer 214 may be smaller than a distance H4 from the upper surface of the second cell gate capping pattern 313 to a lower surface of the second cell gate conductive layer 314.

A thickness of the first insulating liner layer 218 may be the same as that of the second insulating liner layer 318. The thickness of the first insulating liner layer 218 and the thickness of the second insulating liner layer 318 may be those in the fourth direction DR4.

In the semiconductor device according to some embodiments, the first cell gate structure 210 may correspond to the cell gate structure 110 of FIG. 4. In this case, the first insulating liner layer 218 may correspond to the insertion portion 111_IP of the cell gate insulating layer 111 of FIG. 4. The first cell gate insulating layer 211 may correspond to the cell gate insulating layer 111 of FIG. 4. In an implementation, the first cell gate insulating layer 211 may include an upper portion and a lower portion, which have their respective thicknesses different from each other. For another example, the upper portion of the first cell gate insulating layer 211 may include a stair shape.

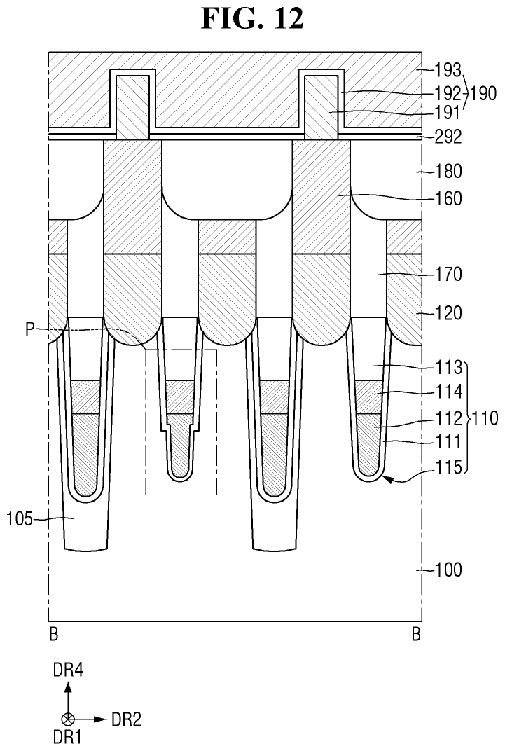

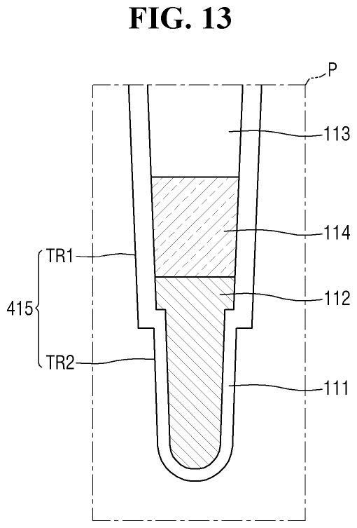

FIG. 12 is a view showing a semiconductor memory device according to example embodiments. FIG. 13 is an enlarged view showing a region P of FIG. 12. For convenience of description, redundant portions repeated with those described with reference to FIGS. 1 to 6 will be briefly described or omitted.

Referring to FIGS. 12 and 13, in the semiconductor device according to some embodiments, a cell gate structure 110 may include cell gate trenches 115 and 415, cell gate insulating layers 111 and 411, a cell gate electrode 112, a cell gate capping pattern 113 and a cell gate conductive layer 114. The description of the cell gate trench 115 may be the same as that described above. Hereinafter, the cell gate trench 415 will be described based on differences from the cell gate trench 115.

The cell gate trench 415 may include a first trench TR1 and a second trench TR2. The second trench TR2 may be below the first trench TR1. A width of the first trench TR1 may be greater than that of the second trench TR2.

A sidewall of the cell gate trench 415 may include a stair shape. In an implementation, a sidewall of the first trench TR1 and a sidewall of the second trench RT2 may not be on the same line.

The sidewall of the first trench TR1 and the sidewall of the second trench TR2 may be connected to each other through a connection portion. The first trench TR1 and the second trench TR2 may be distinguished by the connection portion. The connection portion may be parallel with the upper surface of the substrate 100.

The cell gate insulating layer 111 may be extended along sidewalls and a bottom surface of the cell gate trench 415. The cell gate insulating layer 111 may be continuously arranged along an inner wall of the cell gate trench 415. The cell gate insulating layer 111 may be extended along a profile of at least a portion of the cell gate trench 415. The cell gate insulating layer 111 may not include the insertion portion 111_IP.

The cell gate electrode 112 may be on the cell gate insulating layer 111. The cell gate electrode 112 may fill a portion of the cell gate trench 415. In the semiconductor device according to some embodiments, the cell gate electrode 112 may fill the second trench TR2. The cell gate electrode 112 may fill a portion of the first trench TR1. The cell gate conductive layer 114 may be on the cell gate electrode 112. The cell gate conductive layer 114 may be extended along the upper surface of the cell gate electrode 112. Both sidewalls of the cell gate conductive layer 114 may be in contact with the cell gate insulating layer 111.

The cell gate capping pattern 113 may be on the cell gate conductive layer 114. The cell gate capping pattern 113 may fill the cell gate trench 415 remaining after the cell gate electrode 112 and the cell gate conductive layer 114 are formed.

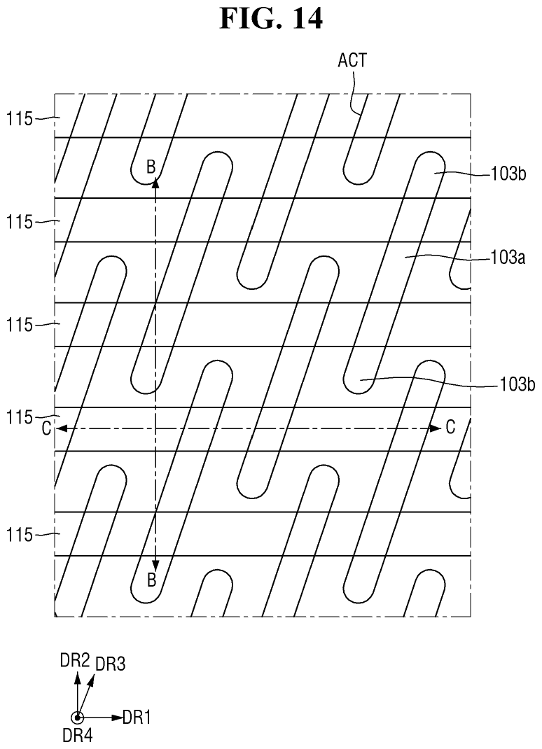

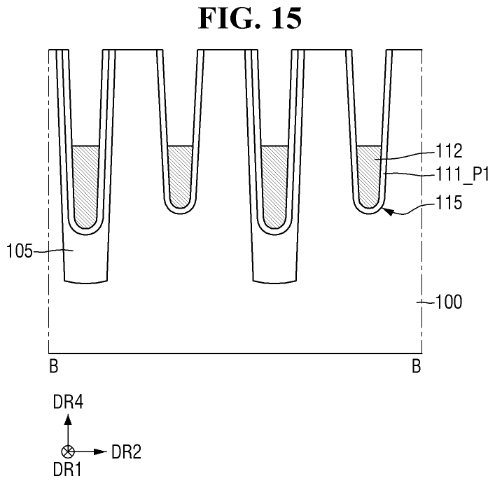

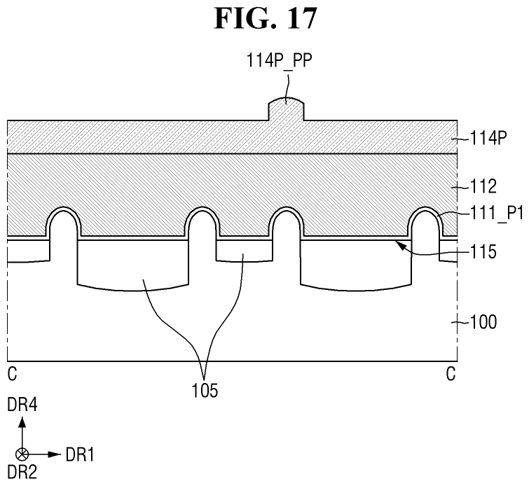

FIGS. 14 to 24 are views showing intermediate steps to describe a method for fabricating a semiconductor memory device according to example embodiments. FIGS. 15, 16, 18, 20, 22 and 24 are cross-sectional views taken along line B-B of FIG. 14. FIGS. 17, 19, 21 and 23 are cross-sectional views taken along line C-C of FIG. 14. In the description of the fabricating method, portions duplicated with those described with reference to FIGS. 1 to 6 will be briefly described or omitted.

Referring to FIG. 14, the cell gate trench 115 may be in the substrate 100. The cell gate trench 115 may be extended in the first direction DR1. The cell gate trench 115 may be formed across the active region ACT.

Referring to FIG. 15, a first pre-cell gate insulating layer 111_P1 and the cell gate electrode 112 may be on the cell gate trench 115. The first pre-cell gate insulating layer 111_P1 may be formed along the sidewalls and the bottom surface of the cell gate trench 115. The cell gate electrode 112 may be on the first pre-cell gate insulating layer 111_P1 to fill the lower portion of the cell gate trench 115.

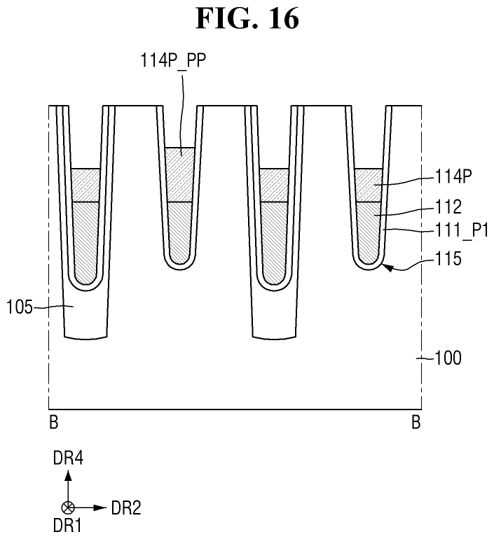

Referring to FIGS. 16 and 17, a pre-cell gate conductive layer 114P may be on the cell gate electrode 112. The pre-cell gate conductive layer 114P may be on sidewalls of the cell gate electrode 112 and the first pre-cell gate insulating layer 111_P1. The pre-cell gate conductive layer 114P may include a protrusion portion 114P_PP. The protrusion portion 114P_PP may be protruded in the fourth direction DR4.

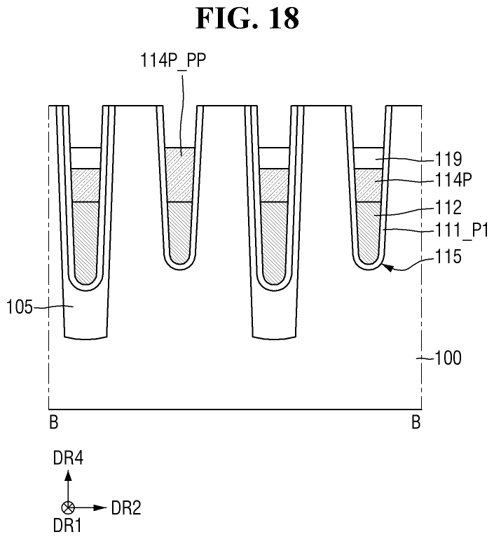

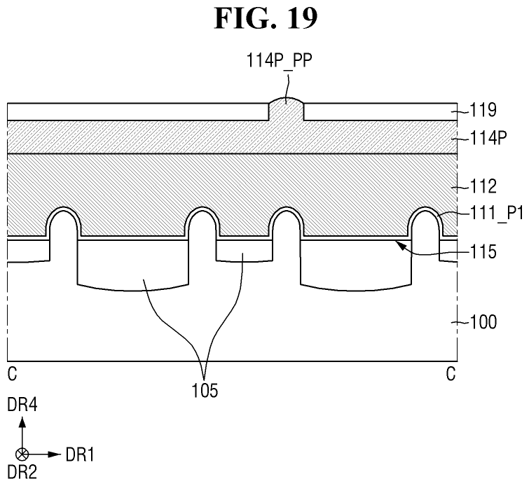

Referring to FIGS. 18 and 19, a mask layer 119 may be on the pre-cell gate conductive layer 114P. The mask layer 119 may be formed by, e.g., a spin coating process.

The mask layer 119 may cover the pre-cell gate conductive layer 114P and expose the protrusion portion 114P_PP. The mask layer 119 may fully cover the pre-cell gate conductive layer 114P and the protrusion portion 114P_PP. An upper portion of the first pre-cell gate insulating layer 111_P1 may be exposed.

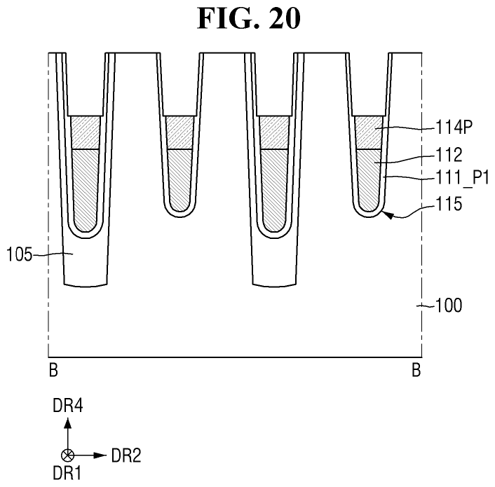

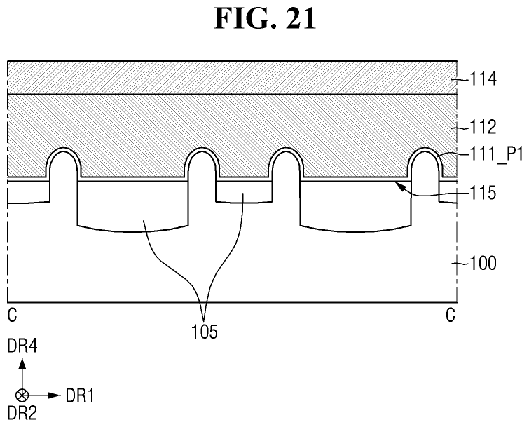

Referring to FIGS. 20 and 21, the mask layer 119 and the protrusion portion 114P_PP may be etched so that the cell gate conductive layer 114 may be formed.

The mask layer 119 and the protrusion portion 114P_PP may be removed by an etching process. An etching material having no etch selectivity with respect to the mask layer 119 and the protrusion portion 114P_PP may be used for the etching process. As a result, the mask layer 119 and the protrusion portion 114P_PP may be removed together.

As the etching process is performed, the exposed first pre-cell gate insulating layer 111_P1 may be partially removed. In an implementation, a thickness of the upper portion of the first pre-cell gate insulating layer 111_P1 may be reduced.

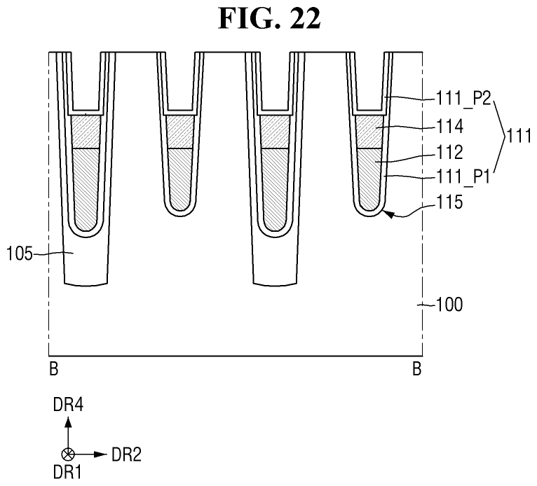

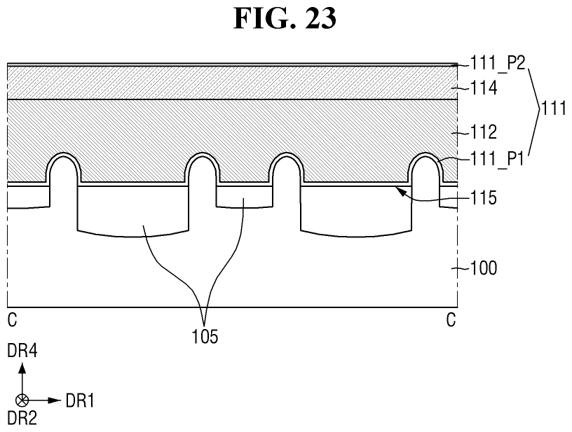

Referring to FIGS. 22 and 23, a second pre-cell gate insulating layer 111_P2 may be on the upper surface of the cell gate conductive layer 114 and the first pre-cell gate insulating layer 111_P1.

The second pre-cell gate insulating layer 111_P2 may be formed by, e.g., an atomic layer deposition (ALD) process. The second pre-cell gate insulating layer 111_P2 may include the same material as that of the first pre-cell gate insulating layer 111_P1. A boundary between the second pre-cell gate insulating layer 111_P2 and the first pre-cell gate insulating layer 111_P1 may not be distinguished. In an implementation, the first pre-cell gate insulating layer 111_P1 and the second pre-cell gate insulating layer 111_P2 may correspond to the cell gate insulating layer 111 of FIG. 4.

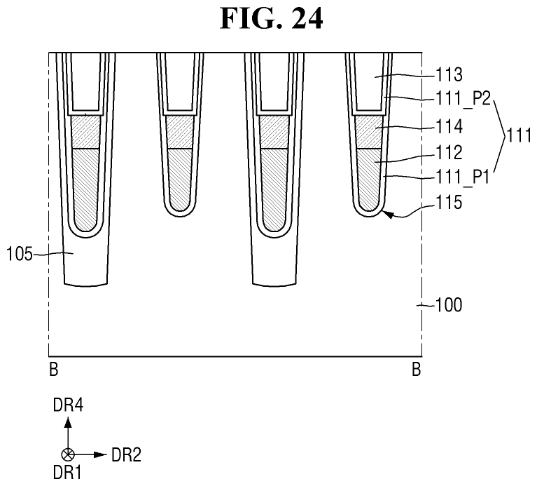

Referring to FIG. 24, the cell gate capping pattern 113 may be on the second pre-cell gate insulating layer 111_P2. In an implementation, the cell gate capping pattern 113 may be formed by forming a capping layer on an entire surface of the substrate 100 and then performing a planarization process. At this time, a portion of the cell gate insulating layer 111 covering the upper surface of the substrate 100 may be removed.

Then, the bit line structure 140ST extended in the second direction DR2 may be on the substrate 100. The bit line structure 140ST may include a cell conductive line 140, a cell line capping layer 144 and a bit line spacer 150.

The storage contact 120, the storage pad 160 and the information storage 190 may be on the storage connection portion 103b of the active region ACT. The information storage 190 may include a lower electrode 191, a capacitor dielectric layer 192 and an upper electrode 193.

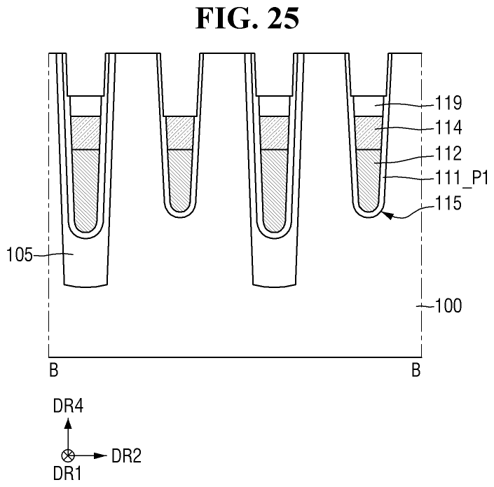

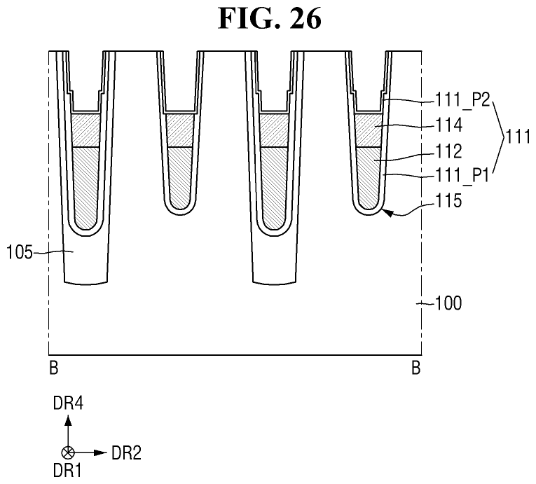

FIGS. 25 and 26 are views showing intermediate steps to describe a method for fabricating a semiconductor memory device according to example embodiments. For convenience of description, portions duplicated with those described with reference to FIGS. 1 to 7 and FIGS. 14 to 24 will be briefly described or omitted.

For reference, the fabricating method of FIGS. 14 to 19 may be equally applied to the fabricating method according to this embodiment. The following description will be given subsequently to FIG. 19.

Referring to FIG. 25, the protrusion portion 114_PP may be etched so that the cell gate conductive layer 114 may be formed.

The protrusion portion 114P_PP may be removed by an etching process. An etching material having etch selectivity with respect to the mask layer 119 and the protrusion portion 114P_PP may be used for the etching process. As a result, the mask layer 119 may not be removed, and only the protrusion portion 114P_PP may be removed.

As the etching process is performed, the exposed first pre-cell gate insulating layer 111_P1 may be partially removed. In an implementation, the thickness of the upper portion of the first pre-cell gate insulating layer 111_P1 may be reduced.

Referring to FIG. 26, the mask layer 119 may be removed, and a second pre-cell gate insulating layer 111_P2 may be formed.

The mask layer 119 may be removed by an ashing process or a strip process, and the upper surface of the cell gate conductive layer 114 may be exposed. The second pre-cell gate insulating layer 111_P2 may be on the upper surface of the cell gate conductive layer 114 and the first pre-cell gate insulating layer 111_P1. The second pre-cell gate insulating layer 111_P2 may include the same material as that of the first pre-cell gate insulating layer 111_P1. A boundary between the second pre-cell gate insulating layer 111_P2 and the first pre-cell gate insulating layer 111_P1 may not be distinguished. In an implementation, the first pre-cell gate insulating layer 111_P1 and the second pre-cell gate insulating layer 111_P2 may correspond to the cell gate insulating layer 111 of FIG. 7.

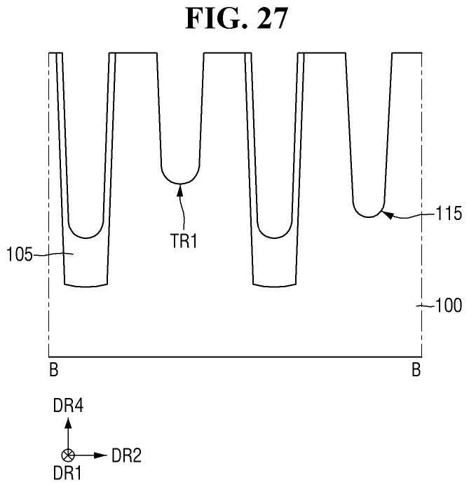

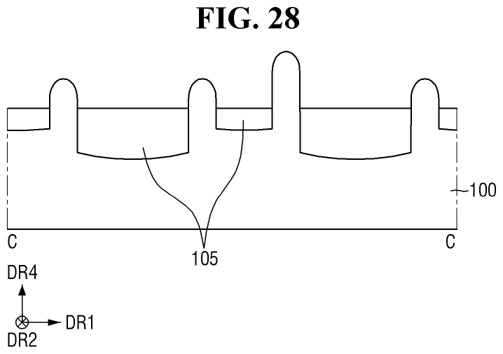

FIGS. 27 to 32 are views showing intermediate steps to describe a method for fabricating a semiconductor memory device according to example embodiments. Referring to FIG. 27 and FIG. 28, the cell gate trench 115 and the first trench TR1 may be in the substrate 100.

The first trench TR1 may be a trench, which has a low depth, among a plurality of cell gate trenches 115. In an implementation, a depth of the first trench TR1 may be smaller than that of the cell gate trench 115. The first trench TR1 may be in the substrate 100. The first trench TR1 may be in the cell element isolation layer 105.

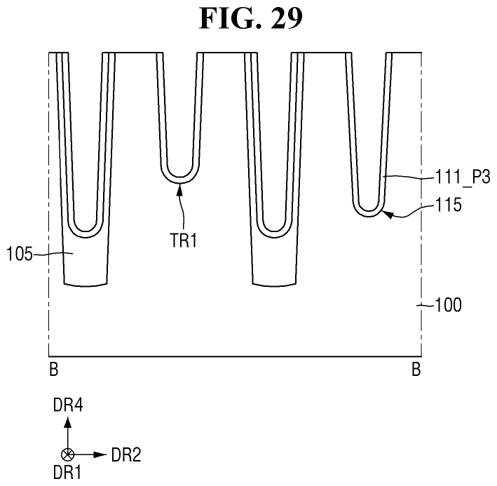

Referring to FIG. 29, a third pre-cell gate insulating layer 111_P3 may be on the cell gate trench 115 and the first trench TR1. The third pre-cell gate insulating layer 111_P3 may be formed along sidewalls and a bottom surface of the cell gate trench 115. The third pre-cell gate insulating layer 111_P3 may be formed along sidewalls and a bottom surface of the first trench TR1. The third pre-cell gate insulating layer 111_P3 may include an oxide.

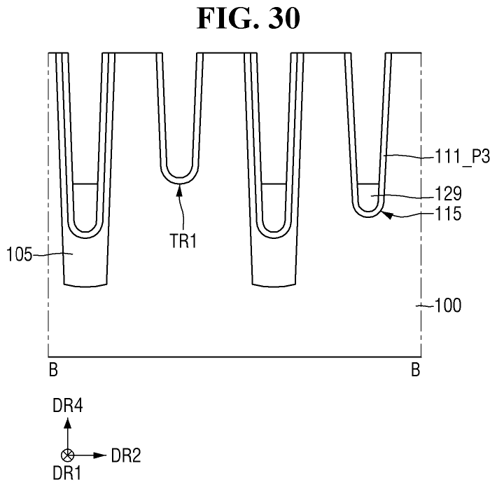

Referring to FIG. 30, a mask layer 129 may be on the cell gate trench 115. The mask layer 129 may be formed by, e.g., a spin coating process. The mask layer 129 may not be on the first trench TR1. The mask layer 129 may protect the cell gate trench 115 in a subsequent etching process.

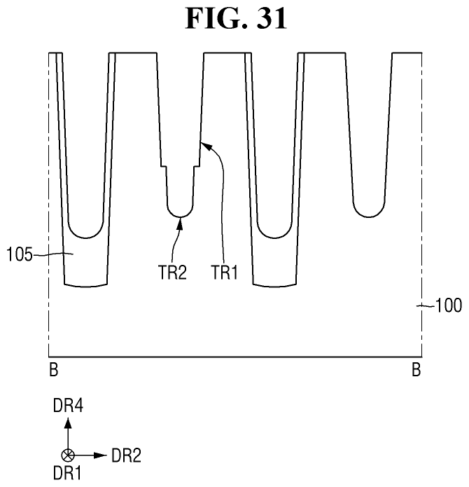

Referring to FIG. 31, the second trench TR2 may be below the first trench TR1. The second trench TR2 may be below the first trench TR1, and may be formed by using the mask layer 129 as a mask. The third pre-cell gate insulating layer 111_P3 and the mask layer 129 may be removed. In an implementation, the third pre-cell gate insulating layer 111_P3 and the mask layer 129 may be removed by an ashing process or a strip process.

The width of the second trench TR2 may be smaller than that of the first trench TR1. The sidewall of the first trench TR1 may not be on the same line as that of the second trench TR2.

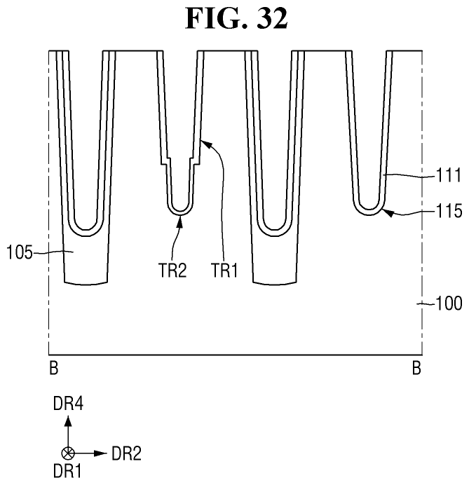

Referring to FIG. 32, the cell gate insulating layer 111 may be on the cell gate trench 115, the first trench TR1 and the second trench TR2. The cell gate insulating layer 111 may be conformally formed on the sidewalls and the bottom surface of the cell gate trench 115. The cell gate insulating layer 111 may be conformally formed on the sidewalls and the bottom surface of the second trench TR2 and the sidewalls of the first trench TR1.

Subsequently, the cell gate electrode 112 may be formed on the cell gate insulating layer 111. The cell gate electrode 112 may fill the second trench TR2. A portion of the cell gate electrode 112 may fill a lower portion of the first trench TR1. The cell gate conductive layer 114 and the cell gate capping pattern 113 may be on the cell gate electrode 112.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

By way of summation and review, with the increase in the degree of integration of the semiconductor device, the design rule for components of the semiconductor device has been reduced.

In highly scaled semiconductor devices, a process of forming a plurality of wiring lines and a plurality of buried contacts (BC) between the wiring lines has become increasingly complex and difficult. An object of the present disclosure is to provide a semiconductor memory device that may improve reliability and performance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor memory device, comprising:
a substrate including an active region;
a cell gate structure in the substrate and extended in a first direction, the cell gate structure including a cell gate trench, a cell gate insulating layer along an inner wall of the cell gate trench, a cell gate electrode on the cell gate insulating layer, a cell gate conductive layer on the cell gate electrode and a cell gate capping pattern filling the cell gate trench;
a bit line structure crossing the cell gate structure; and
an information storage connected to the active region, wherein:
the cell gate insulating layer includes an insertion portion between the cell gate conductive layer and the cell gate capping pattern, a lower portion in contact with the cell gate conductive layer, and an upper portion in contact with the cell gate capping pattern, and
a first thickness of a first portion of the upper portion of the cell gate insulating layer is greater than a second thickness of the lower portion of the cell gate insulating layer.

2. The semiconductor memory device as claimed in claim 1, wherein the insertion portion of the cell gate insulating layer separates the cell gate conductive layer from the cell gate capping pattern.

3. The semiconductor memory device as claimed in claim 1, wherein the upper portion of the cell gate insulating layer includes a step shape in view of a cross-sectional area.

4. The semiconductor memory device as claimed in claim 1, wherein:
the upper portion of the cell gate insulating layer includes the first portion and a second portion between the first portion and the lower portion of the cell gate insulating layer, and
the first thickness is different from that of a third thickness of the second portion.

5. The semiconductor memory device as claimed in claim 4, wherein the first thickness of the first portion is smaller than the third thickness of the second portion.

6. The semiconductor memory device as claimed in claim 4, wherein the first thickness of the first portion is equal to the second thickness of the lower portion of the cell gate insulating layer.

7. The semiconductor memory device as claimed in claim 1, wherein the cell gate insulating layer surrounds the cell gate conductive layer.

8. A semiconductor memory device, comprising:
a substrate including an active region;
a first cell gate trench in the substrate, having a first width;
a first cell gate insulating layer along a first inner wall of the first cell gate trench;
a first cell gate electrode on the first cell gate insulating layer;
a first cell gate conductive layer on the first cell gate electrode;
a first insulating liner layer on the first cell gate conductive layer;
a first cell gate capping pattern on the first insulating liner layer;
a second cell gate trench in the substrate, having a second width greater than the first width;
a second cell gate insulating layer along a second inner wall of the second cell gate trench;
a second cell gate electrode on the second cell gate insulating layer;
a second cell gate conductive layer on the second cell gate electrode;
a second insulating liner layer on the second cell gate conductive layer; and
a second cell gate capping pattern on the second insulating liner layer,
wherein a first distance from an upper surface of the first cell gate capping pattern to an upper surface of the first cell gate conductive layer is equal to a second distance from an upper surface of the second cell gate capping pattern to an upper surface of the second cell gate conductive layer.

9. The semiconductor memory device as claimed in claim 8, wherein a third distance from the upper surface of the first cell gate capping pattern to an upper surface of the first cell gate electrode is smaller than a fourth distance from the upper surface of the second cell gate capping pattern to an upper surface of the second cell gate electrode.

10. The semiconductor memory device as claimed in claim 8, wherein a first thickness of the first insulating liner layer is equal to a second thickness of the second insulating liner layer.

11. The semiconductor memory device as claimed in claim 8, wherein a third thickness of the first cell gate conductive layer is different from a fourth thickness of the second cell gate conductive layer.

12. The semiconductor memory device as claimed in claim 11, wherein the third thickness of the first cell gate conductive layer is smaller than the fourth thickness of the second cell gate conductive layer.

13. The semiconductor memory device as claimed in claim 8, wherein:
the first cell gate insulating layer includes a lower portion that is in contact with the first cell gate conductive layer and an upper portion that is in contact with the first cell gate capping pattern, and
a fifth thickness of the upper portion of the first cell gate insulating layer is greater than a sixth thickness of the lower portion of the first cell gate insulating layer.

14. The semiconductor memory device as claimed in claim 13, wherein the upper portion of the first cell gate insulating layer includes a step shape in view of a cross-sectional area.

15. The semiconductor memory device as claimed in claim 8, further comprising:
a bit line structure crossing the first cell gate electrode; and
an information storage connected to the active region.

16. A semiconductor memory device, comprising:
a substrate including an active region;
a cell gate structure in the substrate and extended in a first direction, including a cell gate trench, a cell gate insulating layer along an inner wall of the cell gate trench, a cell gate electrode on the cell gate insulating layer, a cell gate conductive layer on the cell gate electrode and a cell gate capping pattern filling the cell gate trench;
a bit line structure crossing the cell gate structure; and
an information storage connected to the active region, wherein:
the cell gate trench includes a first trench and a second trench below the first trench, and
a first sidewall of the first trench and a second sidewall of the second trench are not on the same line.

17. The semiconductor memory device as claimed in claim 16, wherein the cell gate insulating layer includes a first step shape in view of a cross-sectional area.

18. The semiconductor memory device as claimed in claim 16, wherein a width of the first trench is greater than that of the second trench.

19. The semiconductor memory device as claimed in claim 16, wherein a third sidewall of the cell gate trench includes a second step shape in view of a cross-sectional area.

20. The semiconductor memory device as claimed in claim 16, wherein an upper portion of the cell gate electrode is in the second trench.
